(19) United States
(12) Patent Application Publication
(10) Pub. No.: US 2003/0072401 A1
(43) Pub. Date: Apr. 17, 2003

(54) Frequency or phase-locked loop provided with improved stability technique

(76) Inventor: Gerrit Willem Den Besten, Eindhoven (NL)

Correspondence Address: Michael E. Marion, c/o U.S. PHILIPS CORPORATION, Intellectual Property Department, 580 White Plains Road, Tarrytown, NY, 10591, US

(21) Appl. No.: 10/241,134

(22) Filed: Sep. 11, 2002

(30) Foreign Application Priority Data
Sep. 17, 2001 (EP) 01203509.3

(51) Int. Cl. H03D 3/24

(52) U.S. Cl. 375/376

(57) ABSTRACT

An electronic circuit comprising a frequency or phase-locked loop (PLL) comprising a first input terminal (1) coupled to receive a first input signal (D); a second input terminal (2) coupled to receive a second input signal (CLK); detection means (DMNS) for comparing the frequency or phase of the first input signal (D) with the frequency or phase of the second input signal (CLK), respectively, and for supplying directly or via a charge pump (CHPPMP) a control voltage (V_{cntrl}) as a result of the comparison of the first (D) and second (CLK) input signals; a control transistor (T₀) having a first main terminal and a control terminal which are coupled to receive the control voltage (V_{cntrl}) and having a second main terminal for supplying a control current (I_{cntrl}) responsive to the control voltage (V_{cntrl}); a capacitor (C) coupled in between the first main terminal and the control terminal; a current controlled oscillator (CCO) having an input terminal (CCO_{I}) coupled to receive the control current (I_{cntrl}) and having an output terminal (CCO_{O}) for supplying directly or via frequency dividers the second input signal (CLK) having a frequency or phase which is synchronized with the frequency or phase, respectively, of the first input signal (D); and a stabilizing circuit (STB) for stabilizing the frequency or phase-locked loop (PLL) by adding a zero to the loop transfer function of the frequency or phase-locked loop (PLL). The stabilizing circuit (STB) further comprises a farther charge pump (CHPPMP_{F}) for delivering a compensation current (I_{z}) to the input terminal (CCO_{I}) of the current controlled oscillator (CCO), while the compensation current (I_{z}) may have an approximately zero value, a negative value, or a possitive value dependent on control signals (FUP, FDN) delivered by the detection means (DMNS), and the absolute value of said positive or negative value roughly linearly depends on the control voltage (V_{cntl}).

The invention relates to an electronic circuit comprising a frequency or phase-locked loop comprising a first input terminal coupled to receive a first input signal; a second input terminal coupled to receive a second input signal; detection means for comparing the frequency or phase of the first input signal with the frequency or phase of the second input signal, respectively, and for supplying directly or via a charge pump a control voltage as a result of the comparison of the first and second input signals; a control transistor having a first main terminal and a control terminal which are coupled to receive the control voltage and having a second main terminal for supplying a control current responsive to the control voltage; a capacitor coupled in between the first main terminal and the control terminal; a current controlled oscillator having an input terminal coupled to receive the control current and having an output terminal for supplying directly or via frequency dividers the second input signal having a frequency or phase which is synchronized with the frequency or phase, respectively, of the first input signal; and a stabilizing circuit for stabilizing the frequency or phase-locked loop by adding a zero to the loop transfer function of the frequency or phase-locked loop.

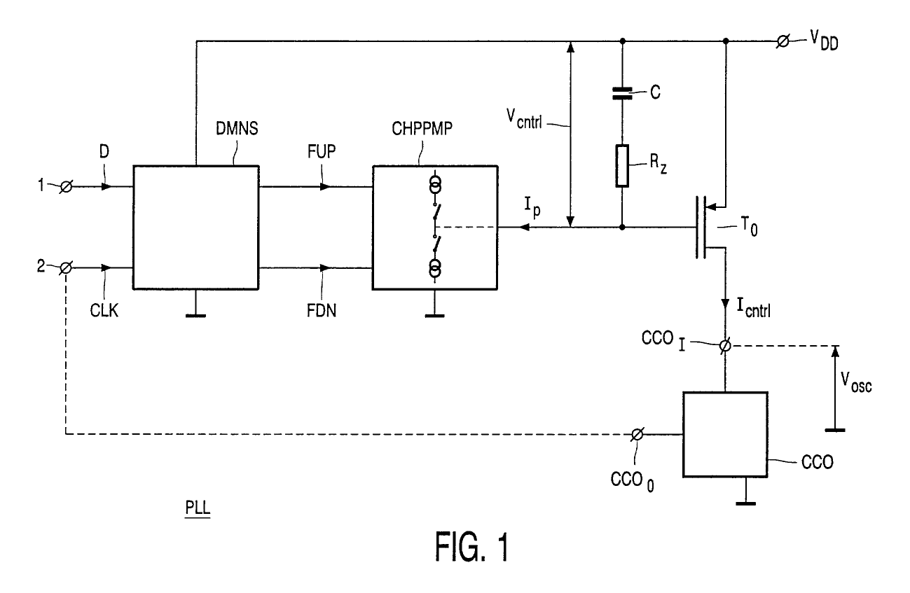

Such an electronic circuit is generally known from the state of the art, as for example shown in FIG. 1. In FIG. 1 a phase-locked loop, further denoted as PLL, is shown. Instead of a PLL also a frequency-locked loop circuit can be used if the detection means DMNS comprises a frequency-comparator instead of a phase-comparator. In many applications the detection means DMNS is a combined frequency/phase-comparator. For clarity reasons the invention will only be described as a PLL.

PLLs are widely used in applications requiring controlled loop gains to ensure optimum time response. If a PLL is used in an integrated circuit, the loop gain of the PLL may vary with temperature, supply voltage, and process dependent parameters such as oxide thickness, sheet resistances, implant concentrations, etcetera. The PLL includes a phase comparator DMNS which receives a (self-clocking) signal D from an asynchronous data source. The phase comparator DMNS supplies a frequency incrementing control signal FUP and a frequency decrementing control signal FDN to a charge pump CHPPMP. The charge pump CHPPMP generates a pump output current Iₚ, which flows in either a positive or negative direction depending on whether one or the other of the respective frequency incrementing/decrementing signals FUP or FDN, is supplied. The pump output current Iₚ is generated with modulated fixed-magnitude pulses.

The Iₚ current pulses will either add charge to or withdraw charge from a charge accumulating capacitor C. Charge accumulation in the capacitor C generates an integrated voltage V_{CNTRL} which is applied to the input of the current controlled oscillator CCO via the control transistor T₀. The CCO produces a (periodic) signal CLK having a variable frequency f_{osc} which is a function of its input voltage. The signal CLK is fed back to input 2 of the phase comparator DMNS while the signal D which is generally aperiodic and is therefore of unknown phase and frequency is supplied to input 1 of the phase comparator DMNS.

Although the signal D is generally aperiodic, it is self-clocking in the sense that is has a fundamental clock frequency which can be derived by averaging over time. The PLL is designed to derive this fundamental clock frequency and to lock on to the phase of the incoming signal D as well. The operation of the PLL will be explained for the case where the signals CLK lags behind the signal D and then for the case where the signal CLK leads the signal D. In situations where incoming edges of the signal arrive before the corresponding edges of the signal CLK (the signal CLK lags), the phase comparator DMNS outputs the frequency incrementing signal FUP to the charge pump CHPPMP and thereby causes the charge pump CHPPMP to supply a positive value of the pump current Iₚ (see the direction of the arrow with regard to Iₚ in FIG. 1). Thus the integrating capacitor C accumulates charge. The input voltage V_{osc} of the CCO, or in fact the current into the input terminal CCO_{I}, is incremented by the accumulated charge and in response the CCO increases the speed of the signal CLK. The frequency f_{osc} of the signal CLK is incremented to a higher value than the fundamental clock frequency of the signal D. The edges of the faster signal CLK then begin to catch up with the edges of the slower signal D. The output frequency f_{osc} drops back to the value of the fundamental clock frequency as the edges of the signal CLK close in on the edges of the signal D. Once the signal CLK is substantially in phase with the signal D, the phase comparator DMNS ceases to output the frequency incrementing signal FUP and the output frequency f_{osc} is held at a steady-state value which is for practical purposes equal to the fundamental clock frequency of the signal D.

For cases where the signal D edges lag behind the signal CLK edges, the phase comparator DMNS outputs the frequency decrementing signal FDN to the charge pump CHPPMP thereby causing the charge pump CHPPMP to supply a negative value of the pump current Iₚ. Thus the capacitor C discharges, thereby reducing V_{cntrl} and V_{osc} and causing the frequency f_{osc} of the CCO to decrease. This delays the signal CLK edges until the edges of the signal D catch up and align with the signal CLK. The FDN control signal is shut off once phase alignment has been obtained.

Typically, the charge pump is designed to deliver the pump current Iₚ in the form of positive or negative rectangular current pulses. The magnitude of the CCO input voltage V_{osc}, or in fact the current into the input terminal CCO_{I}, is changed by modulating the pulse width of the pump current pulses. A generally linearly combined transfer function results from the counterbalancing effect of the characteristic gain function belonging to the control transistor T₀, the current controlled oscillator CCO, and the chargepump CHPPMP. By the way, in many PLL schematic diagrams a voltage controlled oscillator VCO is shown instead of the current controlled oscillator CCO. This is, however, not a real difference; the control transistor T₀ in combination with the CCO of FIG. 1 forms in fact a VCO.

For stability reasons, a so-called zero is implemented in the loop transfer function of the PLL. In the general state of the art the zero is usually implemented by the addition of a resistor in series with the capacitor C, as is indicated in FIG. 1 by compensation resistor R_{z}. This has, however, the disadvantage that the control voltage V_{cntrl} can easily be disturbed since the control voltage V_{cntrl} is less effectively decoupled by the capacitor C as a result of the addition of the compensation resistor R_{z}.

It is an object of the invention to provide an electronic circuit comprising a frequency or phase-locked loop which does away with above disadvantage.

To this end, according to the invention, the stabilizing circuit comprises a further charge pump for delivering a compensation current to the input terminal of the current controlled oscillator, while the compensation current may have an approximately zero value, a negative value, or a possitive value depending on control signals delivered by the detection means, and the absolute value of said positive or negative value roughly linearly depends on the control voltage.

By these measures the desired zero for stability reasons is implemented without using a resistor in series with the capacitor. Therefore, the control voltage cannot easily be disturbed, since the capacitor also functions very effectively as a decoupling means.

U.S. Pat. No. 5,942,947 shows an alternative solution which needs a digital damping circuit for implementing the zero. The solution according to the invention does not need such digital circuitry.

The stabilizing circuit can be used in several ways. It is for instance possible to apply a transistor in which the drain or collector supplies a reference current for the further charge pump, because a resistor is connected in series with the source or emitter, and the gate or base, and a node of the resistor, which node is not connected to said source or emitter, receives the control voltage across the capacitor. The value of the resistor must be high in comparison with 1/g_{M} of said transistor, or, alternatively, the g_{M} of the transistor must be enhanced by the addition of an amplifier. The enhancement of the g_{M} of a transistor by an amplifier is well known in the prior art.

In an embodiment of the invention a field effect transistor is used as the control transistor, the former having a source, a drain, and a gate which respectively form the first main terminal, the second main terminal, and the control terminal of the control transistor, and the stabilizing circuit further comprises a first field effect transistor; a second field effect transistor; a third field effect transistor; a fourth field effect transistor; a current mirror having an input coupled to the drain of the first transistor and an output coupled to the drain of the fourth transistor; and means for supplying a DC-voltage between the drain and the gate of the fourth transistor, the sources of the third and fourth transistors being coupled to the source of the control transistor, the gate of the third transistor being coupled to the gate of the fourth transistor, the source of the first transistor being coupled to the drain of the third transistor, the source of the second transistor being coupled to the drain of the fourth transistor, the gates of the first and second transistors being coupled to the gate of the control transistor, and a reference input of the further charge pump being coupled to the current mirror in a manner that said absolute value is approximately linearly dependent on the current through the input of the current mirror.

This embodiment has the advantage that no resistor is needed at all.

Further advantageous embodiments are specified in further dependent claims.

The invention will be described in more detail with reference to the accompanying drawing, in which:

FIG. 1 is a circuit diagram of an electronic circuit comprising a known PLL;

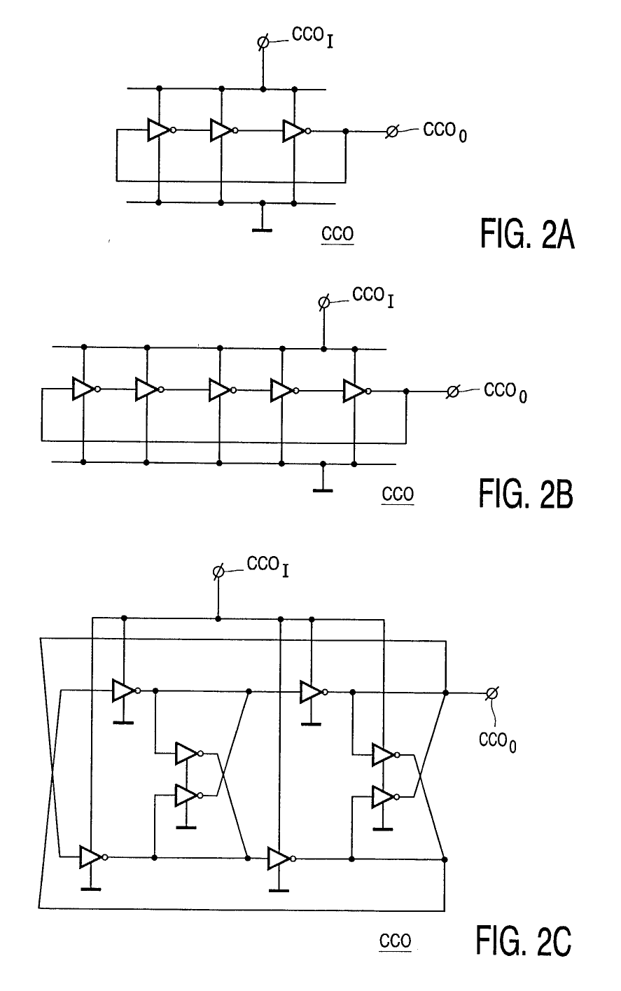

FIG. 2 shows circuit diagrams of current or voltage controlled oscillators which can be used in PLLs;

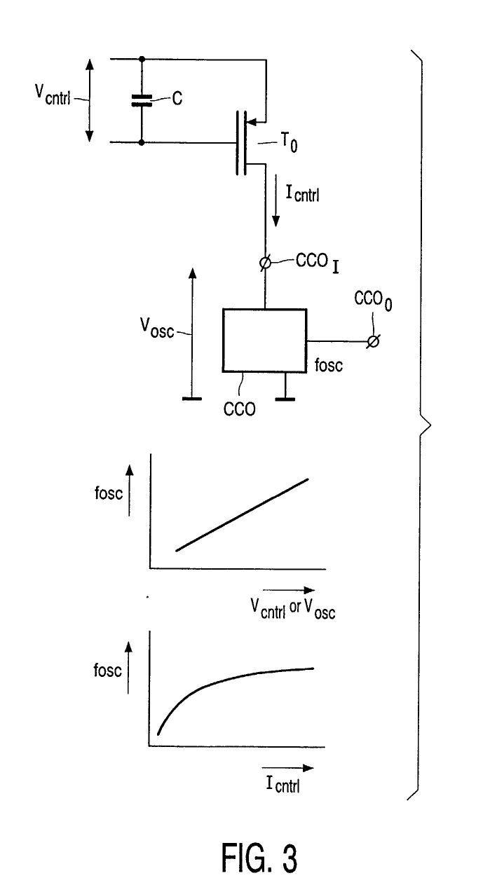

FIG. 3 shows a diagram of a current controlled oscillator and a control transistor for delivering a control current to the current controlled oscillator in response to a control voltage, and figures for indicating the relation of the frequency of the current controlled oscillator to the control voltage, the current through the current controlled oscillator, and the voltage across the current controlled oscillator;

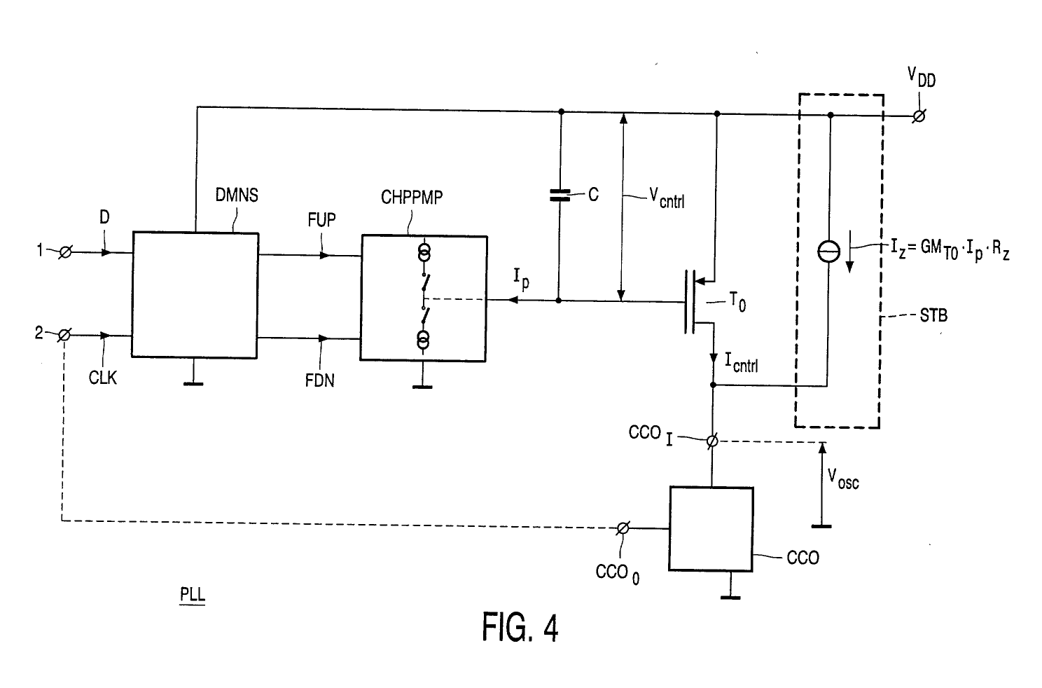

FIG. 4 is a circuit diagram of an electronic circuit comprising a PLL according to the invention;

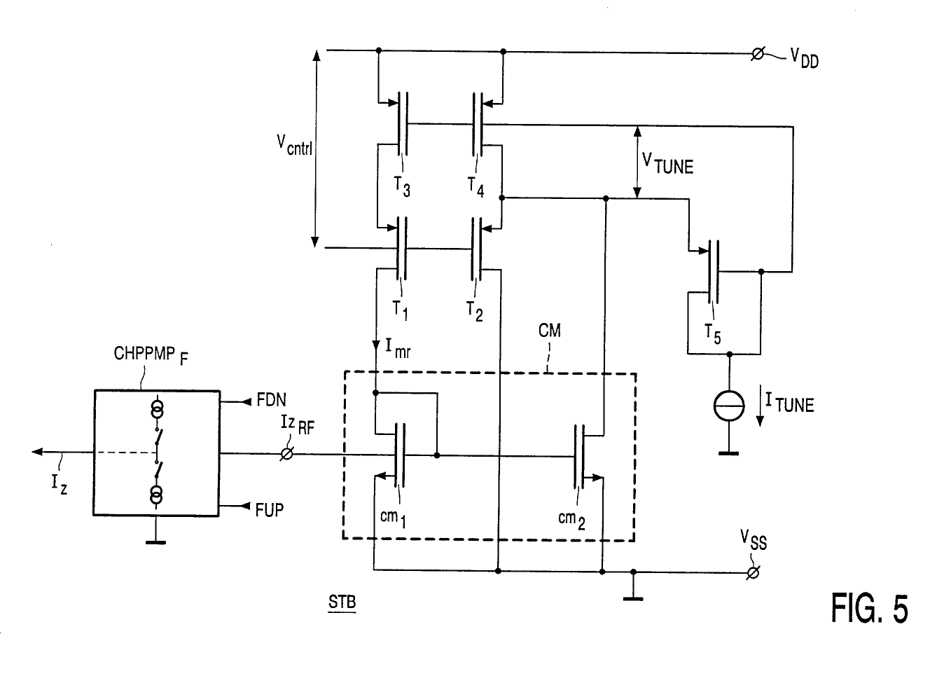

FIG. 5 is a detailed circuit diagram of an inventive stabilizing circuit which can be applied in the inventive PLL according to FIG. 4;

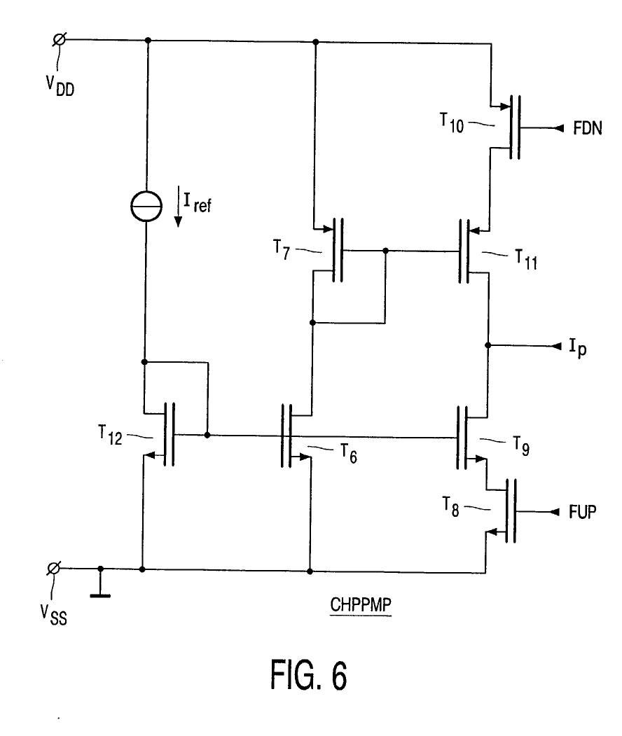

FIG. 6 is a circuit diagram of a charge pump which can be used in PLLs; and

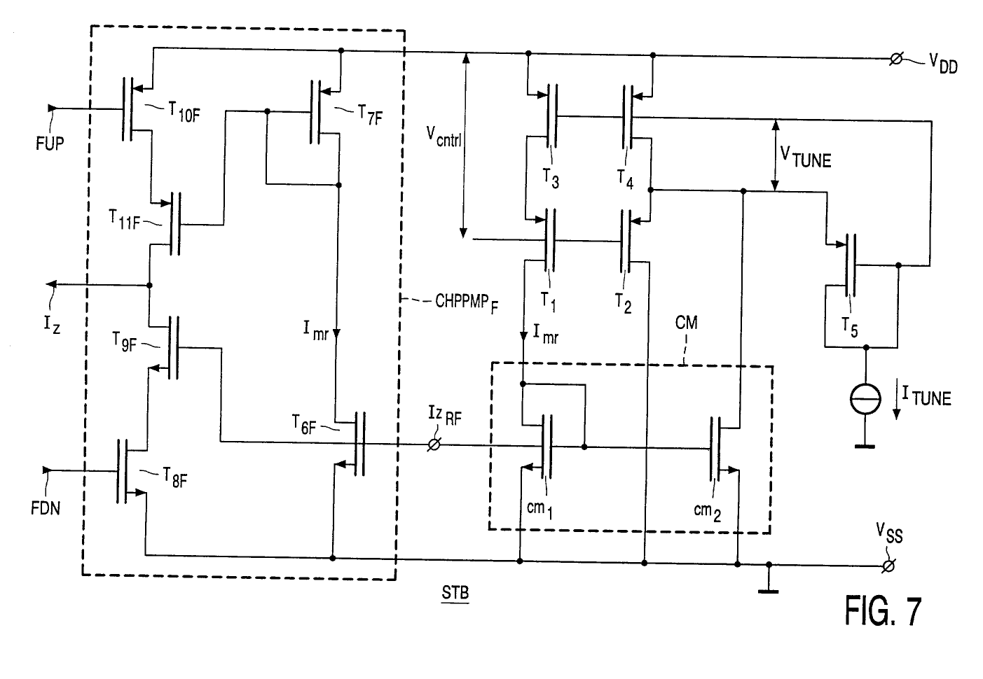

FIG. 7 is a more detailed circuit diagram of the inventive stabilizing circuit according to FIG. 5 in which a use of the further charge pump is shown.

In these figures parts or elements having like functions or purposes bear like reference symbols.

FIG. 4 shows a PLL according to the invention. The differences with respect to the PLL according to FIG. 1 are the removal of the compensation resistor R_{z} and the addition of the stabilizing circuit STB. A field effect transistor T₀ is used as the control transistor T₀ by way of example. In this situation the current controlled oscillator CCO, further denoted as CCO, is preferably used by one of the circuits shown in FIG. 2A, FIG. 2B, or FIG. 2C. By doing so the frequency f_{osc} of the CCO is approximately linearly dependent on the control voltage V_{cntrl} or the voltage V_{osc} across the CCO, as is schematically indicated in FIG. 3.

The stabilizing circuit STB is demonstrated as a current source (in FIG. 4) which can either push (Iₚ is positive) or pull (Iₚ is negative) a current into the input terminal CCO_{I} of the CCO, or do not deliver current at all (Iₚ=0), which is determined by the control signals FUP and FDN. To obtain a good stability, the compensation current I_{z} is determined by formula:

I_{z}=GM_{T0}·Iₚ·R_{z} [1]

in which: GM_{T0} is the transconductance of the control transistor T₀; Iₚ is the pump output current from the charge pump CHPPMP; and R_{z} is the value of the compensation resistor R_{z} which would have been necessary in well-known prior art PLLs.

With the aid of formula [1] the inventive PLL of FIG. 4 is dimensioned as follows for stability purposes: determine the value of the resistor R_{z} in the prior art PLL of FIG. 1, determine the value of the compensation current I_{z} by filling in the value of said resistor R_{z} in formula [1]. So if for example the optimal value of resistor R_{z} in the prior art would have been 100 Ohm, then the value of the compensation current I_{z} is determined by:

I_{z}=100·GM_{TO}·Iₚ

FIG. 5 shows a detailed circuit diagram of a preferred embodiment of the stabilizing circuit STB. The stabilizing circuit STB comprises a first field effect transistor T₁; a second field effect transistor T₂; a third field effect transistor T₃; a fourth field effect transistor T₄; a current mirror CM having an input connected to the drain of the first transistor T₁ and an output connected to the drain of the fourth transistor T₄; and means for supplying a DC-voltage V_{TUNE} between the drain and the gate of the fourth transistor T₄, the sources of the third and fourth transistors are T₃ and T₄ being connected to the source of the control transistor T₀, the gate of the third transistor T₃ being connected to the gate of the fourth transistor T₄, the source of the first transistor T₁ being connected to the drain of the third transistor T₃, the source of the second transistor T₂ being connected to the drain of the fourth transistor T₄ and the gates of the first and the second transistors T₁ and T₂ being connected to the gate of the control transistor T₀. The stabilizing circuit STB further comprises a further charge pump CHPPMP_{F} for delivering a compensation current I_{z} to the input terminal CCO_{I} of the current controlled oscillator CCO.

The current mirror CM comprises a first current mirror transistor cm₁ having a first main terminal, a second main terminal, and a control terminal, the second main terminal and the control terminal being connected to each other and thereby forming the input of the current mirror CM; and a second current mirror transistor cm₂ having a first main terminal connected to the first main terminal of the first current mirror transistor cm₁, a second main terminal which forms the output of the current mirror CM, and a control terminal which is connected to the control terminal of the first current mirror transistor cm₁.

The first main terminals of the first current mirror transistor cm₁ and of the second current mirror transistor cm₂ are connected to the first power supply terminal V_{SS}. The sources of the third and fourth transistors T₃ and T₄ are connected to the second power supply terminal V_{DD}. Field effect transistors or bi-polar transistors may be used as the first and second current mirror transistors cm₁ and cm₂.

A reference input Iz_{RF} of the further charge pump CHPPMP_{F} is connected to the input of the current mirror CM.

A transistor T₅ which is arranged as a diode configuration and which is biased by a current I_{TUNE} is used as the means for supplying the DC-voltage V_{TUNE} by way of example.

The stabilizing circuit STB is dimensioned in a manner that the first and second transistors T₁ and T₂ are in their saturation region, the third and fourth transistors T₃ and T₄ are in their linear region, and in a manner that the drain-source voltage of the third transistor T₃ is approximately two times as high as the drain-source voltage of the fourth transistor T₄. In this way the stabilizing circuit STB delivers a reference current Iₘᵣ which is approximately linearly dependent on the control voltage V_{CNTRL}. It in fact “matches” with formula [1] in that R_{z} is now determined by V_{TUNE} (or I_{TUNE}). By the connection of the reference input Iz_{RF} of the further charge pump CHPPMP_{F} to the input (gate and drain connection of first current mirror transistor cm₁) of the current mirror CM the reference current Iₘᵣ is copied (see FIG. 7) into the further charge pump CHPPMP_{F} to serve as the reference current for the further charge pump CHPPMP_{F}.

FIG. 6 shows a use for the charge pump CHPPMP which comprises N-type field effect transistors T₆, T₈, T₉ and T₁₂, P-type field effect transistors T₇, T₁₀, and T₁₁, and a reference current source I_{ref}. The gates of transistor T₈ and T₁₀ are coupled to receive the control signals FUP and FDN, respectively. The sources of transistors T₆, T₈, and T₁₂ are connected to the first power supply terminal V_{SS}. The sources of transistors T₇ and T₁₀ are connected to the second power supply terminal V_{DD}. The gates of transistors T₇ and T₁₁ and the drains of transistors and the drains of transistors T₆ and T₇ are connected to each other. The gates of transistors T₆, T₉, and T₁₂, and the drain of transistor T₁₂ are connected to each other. The drain of transistor T₈ is connected to the source of transistor T₉. The drain of transistor T₁₀ is connected to the source of transistor T₁₁. The drains of transistors T₉ and T₁₁ are connected to each other to form an output for supplying the pump output current Iₚ The reference current source I_{ref} is coupled to supply a reference current I_{ref} through the transistor T₁₂.

The charge pump CHPPMP according to FIG. 6 operates as follows. Transistors T₁₂ and T₆ form a current mirror which in this example has a mirror ratio of approximately one. Therefore, a reference current I_{ref} is supplied through the transistor T₇.

If the control signal FUP has a logic low level and the control signal FDN has a logic high level, both transistors T₈ and T₁₀ are non-conducting. Therefore, also transistors T₉ and T₁₁ are non-conducting. As a consequence, the value of the pump output current Iₚ is zero.

A substantially zero pump output current Iₚ can alternatively also be obtained if the control signal FUP has a logic high level and the control signal FDN has a logic low level. All 4 transistors T₈-T₁₀ are conducting in that situation. A higher switching frequency can then be reached compared to the former situation. (By mismatch the pump output current Iₚ may slightly differ from zero, however.)

If the control signal FUP has a logic high level and the control signal FDN has a logic high level, both transistors T₁₀ and T₁₁ are again non-conducting. Transistor T₈ is conducting, thereby in fact connecting the source of transistor T₉ to the first power supply terminal V_{SS}. In this situation transistors T₁₂ and T₉ also form a current mirror which in this example has a mirror ratio of approximately one. Therefore, a reference current I_{ref} is supplied through the transistor T₉. As a consequence, the value of the pump output current Iₚ is approximately equal to the value +I_{ref}.

If the control signal FUP has a logic low level and the control signal FDN has a logic low level, both transistors T₈ and T₉ are non-conducting. Transistor T₁₀ is conducting, thereby in fact connecting the source of transistor T₁₁ to the second power supply terminal V_{DD}. In this situation transistors T₇ and T₁₁ also form a current mirror which in this example has a mirror ratio of approximately one. Therefore, a reference current I_{ref} is supplied through the transistor T₁₁. As a consequence, the value of the pump output current Iₚ is approximately equal to the value −I_{ref}.

FIG. 7 shows a more detailed circuit diagram of the inventive stabilizing circuit STB according to FIG. 5 in which a use for the further charge pump CHPPMP_{F} is shown. The further charge pump CHPPMP_{F} is basically used in the same way as the charge pump CHPPMP as shown in FIG. 6. Transistors T_{6F}-T_{11F} in FIG. 7 correspond to transistors T₆-T₁₁ in FIG. 6. The reference current I_{ref} and the transistor T₁₂ are not indicated in FIG. 7. This is because the gate of transistor T_{6F}, which forms the reference input Iz_{RF} of the further charge pump CHPPMP_{F}, is connected to the gate of the transistor cm₁. Therefore, the transistor cm₁ performs in FIG. 7 also the function of transistor T₁₂, whereby the reference current Iₘᵣ replaces the reference current I_{ref}. An important difference between the CHPPMP and the further charge pump CHPPMP_{F} is that the reference current Iₘᵣ is approximately linearly dependent on the control voltage V_{CNTRL}. Another difference is that the gates of transistors T_{8F} and T_{10F} are coupled to receive the control signals FDN and FUP, respectively. This is because the compensation current I_{z} and the control current I_{cntrl} must be in phase, while the control transistor T₀ has an inverting property from its gate to its drain. (See also FIG. 4).

The field effect transistors in the charge pump CHPPMP and the further charge pump CHPPMP_{F} may be fully or partly replaced by bi-polar transistors. However, transistors which form a current mirror cannot be different types of transistors. So if, for example, a bi-polar transistor is used as the transistor cm₁, also transistor cm₂ and transistor T_{6F} must be bi-polar transistors.

Current mirror ratios in the charge pump CHPPMP and the further charge pump CHPPMP_{F} need not necessarily be equal to one.

The inventive PLL (or frequency locked-loop) can be used in an integrated circuit or can be built up by discrete components.

1. An electronic circuit comprising a frequency or phase-locked loop comprising a first input terminal coupled to receive a first input signal; a second input terminal coupled to receive a second input signal; detection means for comparing the frequency or phase of the first input signal with the frequency or phase of the second input signal, respectively, and for supplying directly or via a charge pump a control voltage as a result of the comparison of the first and second input signals; a control transistor having a first main terminal and a control terminal which are coupled to receive the control voltage and having a second main terminal for supplying a control current responsive to the control voltage; a capacitor coupled in between the first main terminal and the control terminal; a current controlled oscillator having an input terminal coupled to receive the control current and having an output terminal for supplying directly or via frequency dividers the second input signal having a frequency or phase which is synchronized with the frequency or phase, respectively, of the first input signal; and a stabilizing circuit for stabilizing the frequency or phase-locked loop by adding a zero to the loop transfer function of the frequency or phase-locked loop, the stabilizing circuit comprising a further charge pump for delivering a compensation current to the input terminal of the current controlled oscillator, while the compensation current may have an approximately zero value, a negative value, or a possitive value depending on control signals delivered by the detection means, and the absolute value of said positive or negative value roughly linearly depends on the control voltage.

2. An electronic circuit as claimed in claim 1, wherein a field effect transistor is used as the control transistor, the former having a source, a drain, and a gate which respectively form the first main terminal, the second main terminal, and the control terminal of the control transistor, and the stabilizing circuit further comprises a first field effect transistor; a second field effect transistor; a third field effect transistor; a fourth field effect transistor; a current mirror having an input coupled to the drain of the first transistor and an output coupled to the drain of the fourth transistor; and means for supplying a DC-voltage between the drain and the gate of the fourth transistor, the sources of the third and fourth transistors being coupled to the source of the control transistor, the gate of the third transistor being coupled to the gate of the fourth transistor, the source of the first transistor being coupled to the drain of the third transistor, the source of the second transistor being coupled to the drain of the fourth transistor, the gates of the first and second transistors being coupled to the gate of the control transistor, and a reference input of the further charge pump being coupled to the current mirror in a manner that said absolute value is approximately linearly dependent on the current through the input of the current mirror.

3. An electronic circuit as claimed in claim 2, wherein the current mirror comprises a first current mirror transistor having a first main terminal, a second main terminal, and a control terminal, the second main terminal and the control terminal being coupled to each other and thereby forming the input of the current mirror; and a second current mirror transistor having a first main terminal coupled to the first main terminal of the first current mirror transistor, a second main terminal forming the output of the current mirror, and a control terminal being coupled to the control terminal of the first current mirror transistor, and the reference input of the further charge pump being coupled to the input of the current mirror.

4. An electronic circuit as claimed in claim 2, wherein the stabilizing circuit is dimensioned in a manner that the first and second transistors are in their saturation region, the third and fourth transistors are in their linear region, and in a manner that the drain-source voltage of the third transistor is approximately two times as high as the drain-source voltage of the fourth transistor.
